(19) United States
(12) Patent Application Publication
(10) Pub. No.: US 2024/0219490 A1
(43) Pub. Date: Jul. 4, 2024

(54) SYSTEMS AND METHODS FOR SILENT FUNCTIONAL MAGNETIC RESONANCE IMAGING (fMRI) USING AIR PARTICLE VACUUM

(71) Applicant: Alex Edson, Scottsdale, AZ (US)

(72) Inventor: Alex Edson, Scottsdale, AZ (US)

(73) Assignee: eBrands Innovations, LLC, Scottsdale, AZ (US)

(21) Appl. No.: 18/092,101

(22) Filed: Dec. 30, 2022

(51) Int. Cl. G01R 33/28; G01R 33/48

(52) U.S. Cl. CPC G01R 33/28; G01R 33/4806

(57) ABSTRACT

A system for performing a silent fMRI scan is disclosed, providing scientists with the novel ability to detect tinnitus and measure tinnitus severity in a subject using a functional magnetic resonance imaging (fMRI) machine. The invention removes all air particles from an enclosed capsule via an air particle vacuum, providing the subject within the capsule's interior with a silent (i.e., zero decibel) fMRI scanning procedure. The subject within the capsule is provided with breathable air via a “scuba-like” breathing system connected to a non-magnetic tank containing purified compressed air. The invention's hemicylindrical design enables the retrofitting of the aforementioned enclosed capsule vacuum chamber onto any fMRI scanning bed without requiring assembly. An optional rebreather system providing breathable air to the subject during the fMRI scan is also disclosed. The rebreather system comprising; a mask, a non-magnetic pure oxygen tank, a non-magnetic diluent tank, connecting tubes, and a rebreather sensor as is known in the arts. Further disclosed is a system for measuring tinnitus severity by processing the subject's fMRI-recorded auditory cortex data into a model, wherein the model is configured to provide one or more classification results, the results being indicative of tinnitus (or the lack thereof) in the subject.

### TECHNICAL FIELD

The embodiments relate generally to functional magnetic resonance imaging (fMRI) machines. More specifically, the invention describes systems and methods that provide subjects with a silent fMRI scanning experience by way of removing all air particles from an enclosed chamber using a vacuum.

### BACKGROUND

It is impossible to overstate the significance of being able to image the brain using an fMRI machine in a silent environment (i.e., zero decibels). For subjects with severe hyperacusis (extreme sensitivity to sound), the thunderous racket is not only excruciating but unbearable—making potentially life-saving scans for brain tumors borderline impossible, even with earplugs. For scientists who desire to objectively measure a subject's tinnitus by analyzing baseline auditory cortex activity, also known as “resting-state data” (i.e., activity, or the lack thereof, in the auditory cortex when no external sound is present), any external sound heard by the subject can materially affect the recorded data.

How can scientists accurately measure a subject's baseline auditory cortex activity when the machine tasked with imaging the auditory cortex is the culprit responsible for distorting the data? Make no mistake: sound emitted from modern-day fMRI machines is a major problem for human subjects and scientists alike.

As a direct result of noise generated from fMRI machines, scientists working on therapeutics for tinnitus have been forced to resort to a vastly inferior imaging technique to measure the effectiveness of their candidates: functional near-infrared spectroscopy (fNIRS).

fNIRS uses infrared light to measure changes in blood-oxygen levels. Unlike an fMRI machine, there are no moving parts—which is why it is silent. However, the fundamental problem with fNIRS is that the infrared light can only measure neural activity near the cortical surface (˜750 to 1000 nm). fNIRS was never intended for deep brain imaging. This is partially why scientists have never been able to achieve a tinnitus-detection accuracy rate above 80% using the relatively primitive fNIRS-based approach.¹ To use a scientific analogy: using fNIRS to image the auditory cortex is akin to trying to measure the depth of an ocean with a ruler. ¹See: “Objective measurement of tinnitus using functional near-infrared spectroscopy and machine learning” URL: https://journals.plos.org/plosone/article?id=10.13731/journal.pone.0241695(Last visited: Dec. 3, 2022.)

To date, millions of dollars and thousands of hours have been invested by various firms and hardware manufacturers to reduce the sound generated from fMRI machines. Progress has been de minimus. Most recently, in 2013, General Electric announced that it had been successful in reducing the noise of its fMRI machine to roughly seventy-seven decibels (77 db)²—a material improvement over the current industry average of approximately 110 decibels—but still a far cry from the zero decibel level required to measure baseline auditory cortex activity. ²See: “The Sound of Silence: GE's Silent Scan Dials Down MRI Noise to a Whisper” URL: https://www.ge.com/news/reports/the-sound-of-silent-scan-dials-downs (Last visited: Dec. 3, 2022.)

When it comes to imaging baseline auditory cortex activity, “quieter” is not quiet enough. Silence is necessary. What is required is a new kind of system that provides subjects with a silent fMRI scanning experience.

To understand how this invention works, one must first understand how sound works from a physics perspective and, to a lesser extent, a medical perspective. The difference is material, as the former deals with the propagation of acoustic waves (i.e., the generation of sound), and the latter primarily concerns the brain's auditory processing (i.e., the perception of sound). Understanding this distinction is fundamental to understanding why tinnitus sufferers hear ringing “in their ears” when no external ringing is actually present (i.e., phantom sound).

The American National Standards Institute (ANSI) defines sound as “oscillation in pressure, stress, particle displacement, particle velocity, etc., propagated in a medium with internal forces (e.g., elastic or viscous), or the superposition of such propagated oscillation.” (Emphasis added.) In common parlance, sound is the back-and-forth movement of molecules.

As a matter of physics, sound cannot travel in a medium that does not provide for the oscillation of particles. To say that another way: if there are no particles to displace, there can be no sound. Such is the scientific essence of the invention disclosed herein.

With respect to the medical definition, sound can be described as the conscious perception of audio.

### SUMMARY OF THE INVENTION

This summary is provided to introduce a variety of concepts in a simplified form that is disclosed further in the detailed description of the embodiments. This summary is not intended to identify key or essential inventive concepts of the claimed subject matter, nor is it intended for determining the scope of the claimed subject matter.

The systems and methods disclosed herein provide for the ability to eliminate all noise propagated by fMRI machines by way of removing all gas particles (i.e., air) from an enclosed chamber using a vacuum.

One of the chief reasons underlying why every drug for tinnitus has failed to date (e.g., OTO-313, most recently) is because scientists did not have an objective way to measure this “subjective” problem—in other words, a definitive system for evaluating the efficacy of tinnitus drug candidates. Currently, scientists structure their randomized controlled trials (RCTs) for tinnitus drug candidates by asking their participants a series of questions from the Tinnitus Handicap Inventory or Tinnitus Functional Index. The participant's answers are then averaged and tracked over the course of the trial's duration. Of course, one need not have a PhD in biochemistry from Harvard-MIT to understand that this archaic approach is outdated and woefully insufficient. For participants with chronic debilitating tinnitus, just drinking a small cup of coffee can dramatically exacerbate tinnitus severity for several hours. And as tinnitus sufferers know all too well, it's not just diet. Stress also plays a considerable role in determining tinnitus severity. For example, hearing a distressing sound, such as a nearby lawnmower or a buzzing fridge, can instantly cause a sufferer's tinnitus severity to skyrocket. Diet and stress and just two examples—there are countless others. The bottom line: using a decades-old survey to assess the efficacy of a drug candidate does not work, especially when the condition at hand can be materially affected by the slightest noise disturbance or dietary choice. For decades, scientists longed for an objective way to measure this subjective problem—it has now arrived.

The invention disclosed herein provides for the world's first objective tinnitus test using an fMRI machine. For the first time in human history, scientists can now objectively detect tinnitus and measure tinnitus severity with unprecedented accuracy. Enabling the imaging of a subject's auditory cortex in a silent environment means that scientists now have a definitive test to evaluate the efficacy of tinnitus drug candidates.

### BRIEF DESCRIPTION OF THE DRAWINGS

A complete understanding of the present embodiments and the advantages and features thereof will be more readily understood by reference to the following detailed description when considered in conjunction with the accompanying drawings wherein:

FIG. 1 illustrates a glass-enclosed tube connected to an exterior air particle vacuum, which has been retrofitted onto an fMRI scanning bed, according to some embodiments;

FIG. 2 illustrates a human subject wearing a rebreather apparatus connected to a pure oxygen tank and a diluent tank inside of a glass-enclosed tube connected to an exterior air particle vacuum, which has been retrofitted onto an fMRI scanning bed, according to some embodiments.

FIG. 2B illustrates a human subject wearing a breathing apparatus connected to a single purified compressed air tank inside of a glass-enclosed tube connected to an exterior air particle vacuum, which has been retrofitted onto an fMRI scanning bed, according to some embodiments;

FIG. 3 illustrates an animal subject strapped to an fMRI scanning bed, according to some embodiments³; ³See: “Raccoons Are Increasingly Popular Lab Test Subjects. Here's Why.” URL: https://www.wsj.com/video/series/daniela-hernadez/raccoons-are-increasingly-popular-lab-test-subjects-heres-why/5E69A666-C1C1-481B-942B-1B9A5B119764 (Last visited: Dec. 5, 2022)

FIG. 4 illustrates an animal subject strapped to an fMRI scanning bed wearing a rebreather apparatus inside of a capsule connected to an exterior air particle vacuum, which has been retrofitted onto an fMRI scanning bed, according to some embodiments; and

FIG. 5 illustrates a human subject wearing bone conduction headphones with a Neuromod Lenire® device placed under the subject's tongue on an fMRI scanning bed.

FIG. 6 illustrates a human subject wearing bone conduction headphones with a Neuromod Lenire® device placed under the subject's tongue inside of a glass-enclosed tube. Unlike the aforementioned Figures, the exterior air particle vacuum is extracting gas from the room housing the fMRI machine, not the glass-enclosed tube itself. Pure oxygen and diluent tanks positioned outside the glass-enclosed tube provide a conduit for breathable air, according to some embodiments;

### DETAILED DESCRIPTION

The specific details of any single embodiment or variety of embodiments described herein are to the described system(s) and method(s) of use. Any specific details of the embodiments are used for demonstration purposes only, and no unnecessary limitations or inferences are to be understood thereon.

Before describing in detail exemplary embodiments, it is noted that the embodiments reside primarily in combinations of components and procedures related to the system. Accordingly, the system components have been represented, where appropriate, by conventional symbols in the drawings (i.e., schematics), showing only those specific details that are pertinent to understanding the embodiments of the present disclosure so as not to obscure the disclosure with details that will be readily apparent to those of ordinary skill in the art having the benefit of the description herein.

In general, the embodiments provided herein relate to systems and methods which provide for the ability to record “baseline auditory cortex activity”—i.e., activity, or the lack thereof, in the auditory cortex, in a silent environment—using an fMRI machine, by way of removing all gas particles (i.e., air) from an enclosed chamber. The principal purpose of the invention is to enable scientists conducting randomized controlled trials (RCTs) to measure the efficacy of tinnitus drug candidates and therapeutic treatments with unprecedented accuracy. Being able to measure a human subject's auditory cortex activity in a silent environment (0.00 decibels) with an fMRI machine means that scientists now have a way to definitively measure whether their potential treatments are actually working, rather than relying on antiquated, subjective, and non-scientific surveys such as the Tinnitus Handicap Inventory or Tinnitus Functional Index, which is currently the standard for tinnitus RCTs.

In one optional aspect, the system features a purified compressed air tank placed at or near the subject's feet; containing ˜78.09% nitrogen, ˜20.95% oxygen, and ˜0.96% of other gases—namely, helium, methane, argon, neon, and krypton. But unlike traditional purified compressed air tanks, such as those found in scuba diving, the tank disclosed herein is comprised exclusively of non-magnetic materials, such as plastic, glass, Plexiglass®, or other non-magnetic material(s), so as not to interfere with the magnetic field generated by the fMRI machine.

In one optional aspect, the system features a rebreather apparatus connected to a pure oxygen tank and a diluent tank. Just like the aforementioned purified compressed air tank, both the pure oxygen tank and the diluent tank are comprised exclusively of non-magnetic materials, such as plastic, glass, Plexiglass®, or other non-magnetic material(s), placed at or near the subject's feet.

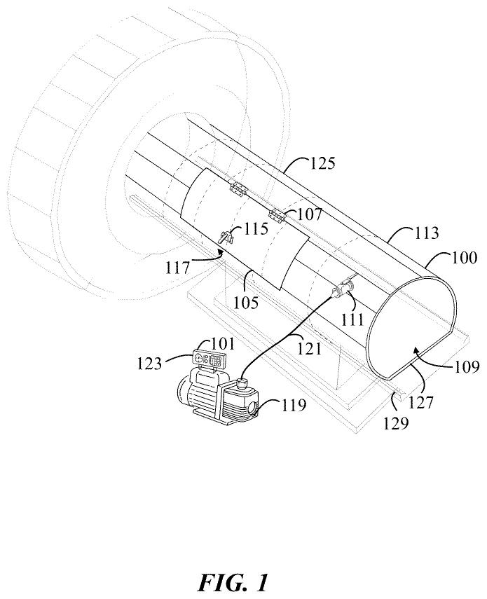

FIG. 1 illustrates a capsule 100 (also referred to herein as the “glass-enclosed tube” or “enclosed chamber”) connected to an exterior air particle vacuum 101, which has been retrofitted onto an fMRI scanning bed 129. The fMRI scanning bed 129 may be a separate component or built into an fMRI machine, as is known in the arts. The capsule 100 includes a capsule door 105 and hinge 107, providing a means for entering, exiting, or accessing the interior 109 of the capsule 100. An exterior capsule valve 111 is attached to the outside 113 of the capsule 100. The exterior capsule valve 111 keeps air particles from entering the interior 109 of the capsule 100 and prevents air particle re-entry if/once the vacuum is turned off. An exterior capsule latch 115 creates an airtight seal once the capsule door 105 is closed by the fMRI operator prior to the commencement of the fMRI scan. An interior capsule latch 117 is provided in case of an emergency to permit the opening of the capsule 105 from the interior 109 by the subject.

In further reference to FIG. 1, a vacuum 119 extracts air particles from the capsule 100 interior 109 during the fMRI scan. One or more tubes 121 attached to the exterior capsule valve 111 connect to the vacuum 119, providing a conduit for air to flow. Air pressure within the interior 109 of the capsule 100 is monitored by a capsule pressure monitor 123 to determine if adequate pressure is reached and to avoid potentially hazardous operating conditions, such as an implosion of the capsule 100.

Rather than utilize a circular tube design, which would not fit within most modern-day fMRI machines, a hemicylindrical tube design is utilized (See 125 and 127). This design includes a flat bottom 127, allowing it to be retrofitted onto any existing fMRI scanning bed 129 without requiring assembly.

In some embodiments, the capsule 100 is comprised of ultra-thin (<2 mm) hardened curved glass forged from a non-aluminosilicate-based process. In several aspects, the capsule valve 111, exterior latch 115, and interior latch 117, may be comprised exclusively of plastic, glass, Plexiglass®, or other non-magnetic material(s).

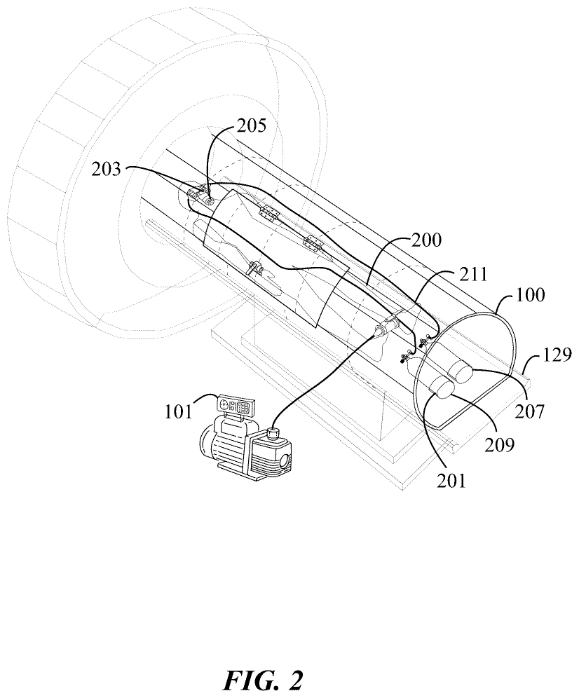

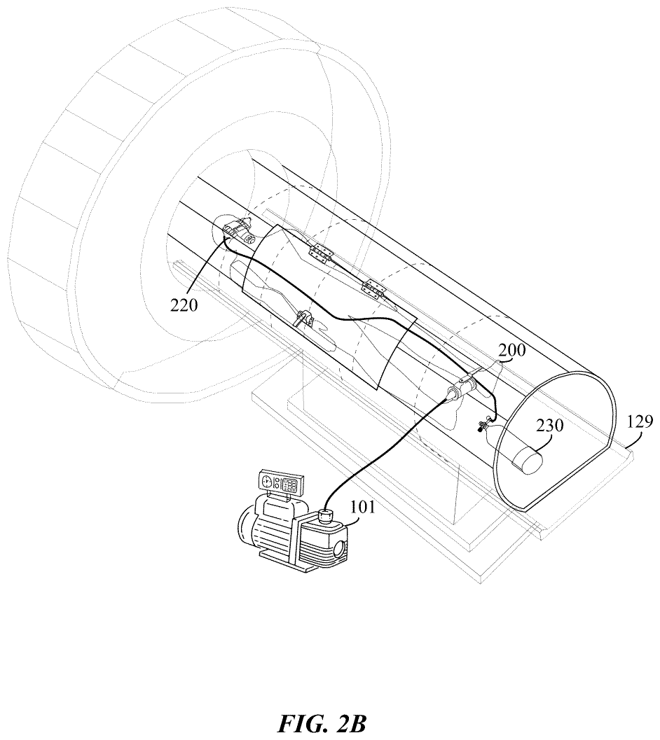

FIG. 2 illustrates a human subject 200 wearing a rebreather apparatus 201 inside of the capsule 100 connected to a vacuum 101, which has been retrofitted onto an fMRI scanning bed 129. A rebreather system 203 includes the rebreather apparatus 201, mask 205, pure oxygen tank 207, diluent tank 209, and connecting tubes 211. The mask 205 is designed to properly fit over the face (at least the nose and mouth) of the human subject 200 and is in communication with the pure oxygen tank 207 and diluent tank 209 via a rebreather sensor to monitor carbon dioxide levels, as is known in the arts. The connecting tubes 211 connect the mask 205 to the pure oxygen tank 207 and the diluent tank 209.

In some embodiments, a purified compressed air tank system may be utilized instead of the rebreather system 203.

The rebreather system 203 is a closed-circuit system, meaning, it permits “rebreathing” of air by recycling unused oxygen content by absorbing carbon dioxide. The rebreather system 203 is materially different from open-circuit breathing apparatuses in which exhaled gases are discharged directly into the environment. In a capsule 100 environment such as this, where the removal of virtually all gas particles is critical to the functionality of the invention, rebreathers enable fMRI scans without the continual running of a vacuum. Put simply, creating a silent capsule is not possible if the subject within the capsule is introducing new gas particles by way of emitting carbon dioxide, unless the vacuum is continually operating throughout the fMRI scan (i.e., removing the newly introduced gas particles at a rate faster than the rate of introduction). The rebreather system 201 is an optional embodiment, while a purified compressed air tank system 213 (see FIG. 2B) is also offered as an embodiment. The advantage of using a rebreather system, as compared to a standard purified compressed air tank system, is that the vacuum does not need to continually operate to remove gas particles. Either version can be utilized to offer a silent environment to subjects within the capsule 100.

FIG. 2B illustrates a human subject 200 wearing a breathing apparatus 220 connected to a single purified compressed air tank 230 inside of an enclosed capsule connected to an exterior air particle vacuum 101, which has been retrofitted onto an fMRI scanning bed 129.

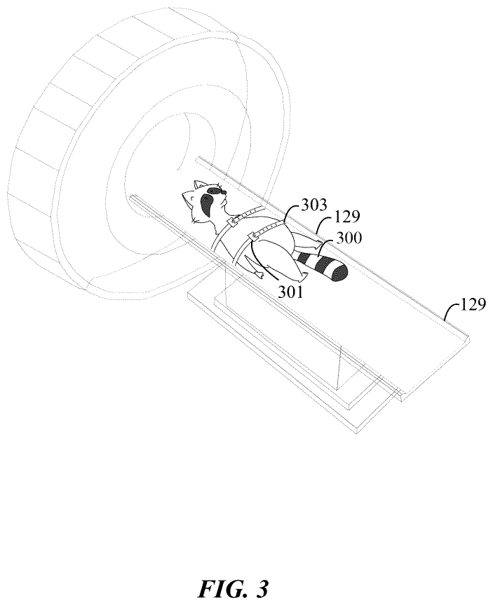

FIG. 3 illustrates an animal subject⁴ 300 strapped to an fMRI scanning bed 129. A restraint system 301 includes one or more straps 303 to restrain the animal during an fMRI scan. One or more straps 303 may be adjustable to accommodate animals, and/or humans, of various sizes. ⁴It is difficult to directly compare the auditory cortex of different species because the brain structures and functions of different animals can vary significantly. However, the auditory cortex of raccoons is likely more similar to that of humans than it is to monkeys, as raccoons and humans are both mammals and have more closely related brain structures and functions. Such is why a raccoon is pictured as the animal subject in the drawings.

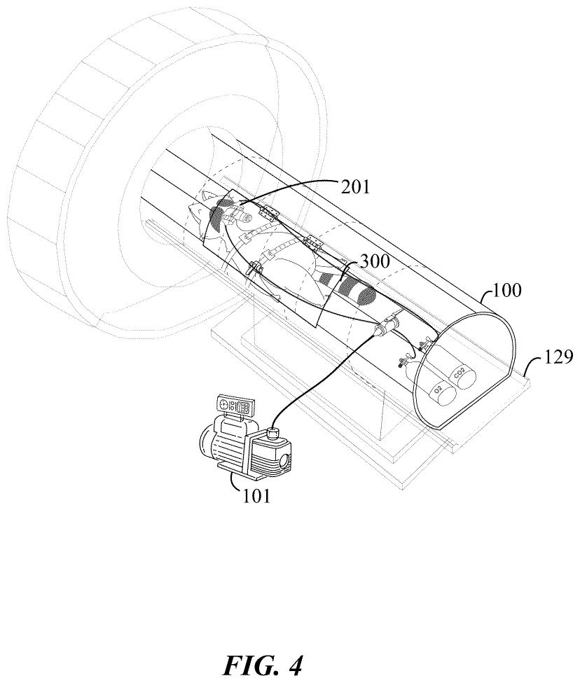

FIG. 4 illustrates an animal subject 300 strapped to an fMRI scanning bed 129 wearing a rebreather apparatus 201 inside of the capsule 100 connected to an exterior air particle vacuum 101, which has been retrofitted onto the fMRI scanning bed 129.

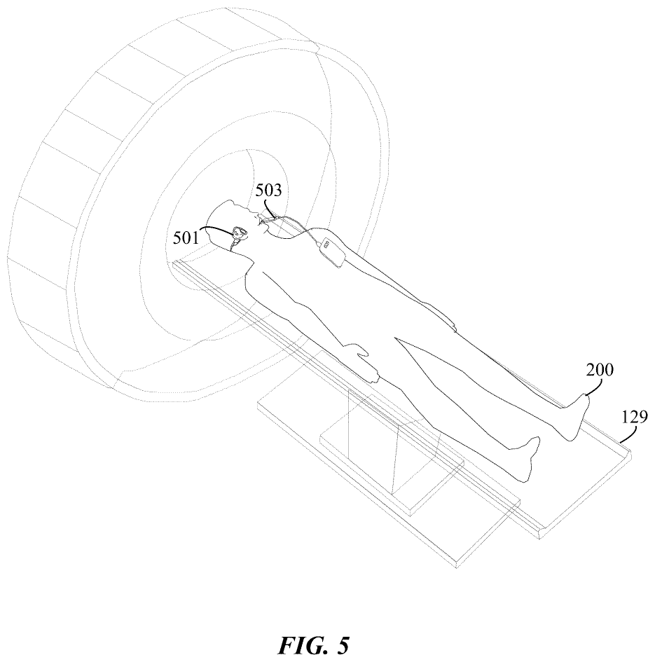

FIG. 5 illustrates a human subject 200 wearing bone conduction headphones 501 with a Neuromod Lenire® device 503 placed under the subject's tongue on an fMRI scanning bed 129.

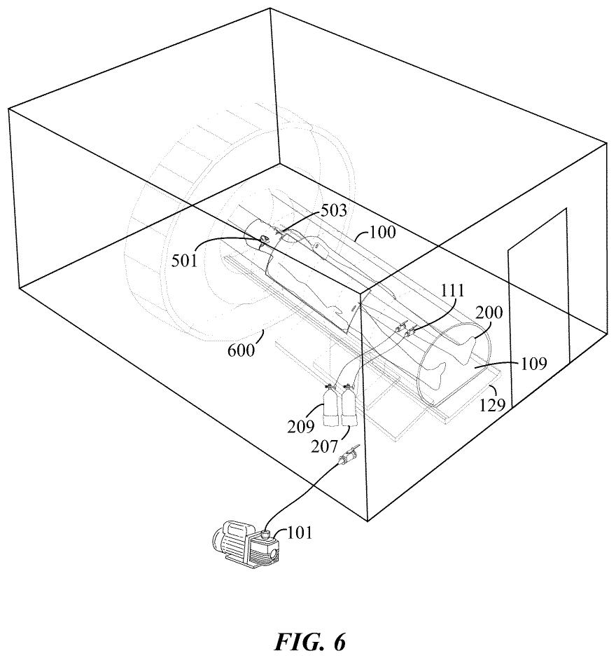

FIG. 6 illustrates a human subject 200 wearing bone conduction headphones 501 with a Neuromod Lenire® device 503 placed under the subject's tongue inside of the capsule 100, which has been retrofitted onto an fMRI scanning bed 129. Unlike the aforementioned Figures, the exterior air particle vacuum 101 is extracting gas from an air-sealed room housing the fMRI machine 600, not the capsule 100 itself. A pure oxygen tank 207 and a diluent tank 209 are positioned outside the capsule 100 and are connected to two separate exterior capsule valves 111 providing breathable air to the human subject 200 within the interior 109 of the capsule 100. This system permits the human subject 200 within the capsule 100 to breathe normally (without wearing a mask apparatus), enabling the Neuromod Lenire® device 503 to be placed under the subject's tongue. Just like each of the aforementioned Figures, the noise of the fMRI machine 600 is not audible to the subject within the interior 109 of the capsule 100.

Prior to this invention, the only way to measure baseline auditory cortex activity was with fNIRS (functional near-infrared spectroscopy), a relatively primitive imaging technique that measures changes in blood-oxygen levels extremely close to the cortical surface (˜750 to 1000 nm). Unlike an fMRI machine, there are no moving parts, allowing for a silent scanning environment. However, the fundamental problem with fNIRS is that infrared light can only measure neural activity extremely close to the cortical surface (˜750 to 1000 nm). fNIRS was never intended for deep brain imaging. This is partially why scientists have never been able to achieve a tinnitus-detection accuracy rate above 80% using the relatively primitive fNIRS-based approach. To use a scientific analogy, using fNIRS to image the auditory cortex is akin to trying to measure the depth of an ocean with a ruler. fMRI scans provide vastly superior imaging data relative to fNIRS scans—there is simply no comparison. The issue, however, is that fMRI machines previously could not be used for measuring resting-state auditory cortex data because of their thunderous noise. The embodiments disclosed herein provide scientists with the novel ability to use fMRI machines to image both a human subject's auditory cortex in a silent environment. This enables an entirely new way to image the region in the brain believed to be responsible for tinnitus—the auditory cortex. Accordingly, scientists can now definitively measure the efficacy of prospective tinnitus drug candidates and therapies by way of analyzing reductions in auditory cortex activity (i.e., neuroplastic restoration).

In addition to playing a critical role in helping scientists create the first-ever drug (and potentially even cure) for tinnitus by providing an objective way to measure what was previously a subjective problem, the invention is also expected to play an equally critical role in developing novel drugs for other debilitating conditions that concern the auditory cortex, including but not limited to; Ménière's disease, auditory neuropathy, Auditory Processing Disorder (APD), cortical deafness, auditory agnosia, and potentially Visual Snow Syndrome (VSS). Furthermore, the invention disclosed herein is also expected to be of great economic value to the U.S. Department of Veterans Affairs Office (the “VA”) by providing the ability to eliminate nearly all tinnitus benefit disability fraud. For the first-time ever, the VA can now verify whether a veteran is actually eligible for tinnitus benefits. It is estimated that the U.S. government currently pays more than $3.7 billion USD in tinnitus benefits every year.⁵ It remains to be seen how many veterans are currently receiving tinnitus disability benefits but do not actually have tinnitus. ⁵See: Veterans Affairs Administration Report “Annual Benefits Report—Compensation” (URL: https://www.benefits.va.gov/REPORTS/abr/docs/2019-compensation.pdf) (Last visited: Dec. 15, 2022)

Many different embodiments have been disclosed herein, in connection with the above description and drawings. It is understood that it would be unduly repetitious to describe and illustrate every combination and sub-combination of these embodiments. Accordingly, all embodiments can be combined in any way and/or combination, and the present specification, including the drawings, shall be construed to constitute a complete written description of all combinations and sub-combinations of the embodiments described herein, and of the manner and process of making and using them, and shall support claims to any such combination or sub-combination.

In one aspect, a method is provided for characterizing tinnitus—i.e., detecting and gauging tinnitus severity (or the lack thereof)—in a subject using functional magnetic resonance imaging (fMRI), the method comprising:
a) receiving fMRI imaging data of the subject's auditory cortex, the processing comprising;
b) inputting said fMRI imaging data into a model, wherein the model is configured to provide one or more classification results, the results being indicative of tinnitus in the subject.

In some embodiments, tinnitus classification results may include the presence or absence of tinnitus in the subject. Additionally, or alternatively, the classification results may include a severity rating of tinnitus in the subject. In some embodiments, the severity rating may categorize the tinnitus into categories, such as:
(a) “Intermittent tinnitus” (i.e., not constant)
(b) “Chronic tinnitus” (aka “persistent tinnitus”—i.e., every waking second); or
(c) “Chronic and severe tinnitus”

In other embodiments, the subject's tinnitus severity rating may be selected from a range of severities. For example, the subject's tinnitus severity rating may be expressed on a numerical scale known as a “T-Score™⁶” (i.e., a number 0 through 100, with zero representing non-existent tinnitus and one hundred representing chronic and severe tinnitus). ⁶“T-Score™⁶” is a trademark of Operation Silence Foundation, a recently launched 501(c)(3) non-profit exclusively focused on advancing tinnitus research, founded by the inventor of the present disclosure, Alex Edson.

In other embodiments, the classification results may also be able to indicate the type of tinnitus experienced by the subject, for example, pulsatile tinnitus, bilateral tinnitus, asymmetric tinnitus, and so forth.

In some embodiments, the machine learning model may comprise of an algorithm or multiple algorithms. In some embodiments, the model may comprise of a trained model. Such model(s) may have been trained with an artificial intelligence (AI) algorithm.

In some embodiments, a supervised machine learning model may be utilized to train an algorithm to characterize tinnitus by adjusting weights and biases of a given model based on a human subject's subjective assessment of their tinnitus. For example, if a human subject with tinnitus answers “yes” to the question of “have you attempted suicide in the past six months because of your tinnitus?” the human subject's answer can be mapped to their corresponding resting-state fMRI scan data, which can be used to train an algorithm, or multiple algorithms.

The model may provide classification results using a classification algorithm. The classification algorithm may be selected from the group including, for example, Naive Bayes; K-nearest neighbor (KILN); Rule Induction; and Artificial Neural Networks (ANN). In other embodiments, alternative classification algorithms or customized (i.e., proprietary) algorithms may be used.

The system may comprise an auditory stimulator configured to deliver an auditory stimulus to the subject. For example, in one aspect, the system may compromise of a bimodal neuromodulation treatment, such as Neuromod's Lenire®. Such stimuli may be configured to evoke a material response in the subject. Somatosensory stimuli may comprise of combining sound and electrical tongue stimulation. With respect to administering sound to the subject via Lenire's over-ear headphones (which would not work in a gas-particle-free environment), substitution may be made for bone conduction headphones. Additionally, or alternatively, a visual stimulus may also be utilized (i.e., trimodal modulation).

In some embodiments, the model may be configured to provide a prognostic measure, indicative of whether a proposed therapy for treating tinnitus is likely to be effective for treating tinnitus in the subject.

Methods for characterizing tinnitus in a subject using functional magnetic resonance imaging (fMRI) according to embodiments of the present disclosure are now described.

An equivalent substitution of two or more elements can be made for any one of the elements in the claims below or a single element can be substituted for two or more elements in a claim. Although elements can be described above as acting in certain combinations and even initially claimed as such, it is to be expressly understood that one or more elements from a claimed combination can, in some cases, be excised from the combination and that the claimed combination can be directed to a sub-combination or variation of sub-combinations.

It will be appreciated by persons skilled in the art that the present embodiments are not limited to what has been particularly shown and described hereinabove. A variety of modifications and variations are possible in light of the above teachings without departing from the following claims.

What is claimed is:

1. A system for performing a silent fMRI scan is disclosed, providing scientists with the novel ability to detect tinnitus and measure tinnitus severity using an fMRI machine, comprising:
i. a non-magnetic tank system comprising of purified compressed air, pure oxygen, and/or diluent;
ii. an enclosed capsule for fMRI machines;
iii. a hemicylindrical capsule enabling the retrofitting of the enclosed capsule onto any fMRI scanning bed without requiring assembly;
iv. an fMRI scanning bed in communication with an fMRI machine;
v. an enclosed capsule including an interior to receive a subject therein;
vi. an exterior air particle vacuum to draw gas particles from the interior of the capsule to provide a silent environment to a subject within the interior of the capsule;
vii. a rebreather system comprised of a rebreather apparatus including: a mask, a (non-magnetic) pure oxygen tank, a (non-magnetic) diluent tank, and connecting tubes, to provide breathable air to a subject during an fMRI scan.

2. The system of claim 1, wherein the capsule is a hemicylindrical tube including a flat bottom, wherein the flat bottom is retrofitted onto an fMRI scanning bed.

3. The system of claim 1, further comprising a capsule air pressure monitor to monitor pressure within the interior of the capsule.

4. The system of claim 1, wherein the silent fMRI scanning procedure is performed to measure a subject's baseline (i.e. resting-state) auditory cortex activity.

5. The system of claim 1, wherein the capsule is comprised of a capsule door and an exterior capsule latch to hermetically seal the capsule.

6. The system of claim 5, further comprising an interior capsule latch to permit the opening of the capsule by the subject from the interior of the capsule.

7. The system of claim 1, wherein a purified compressed air tank system, or rebreather system, is utilized to provide breathable air to the subject during the fMRI scan.

8. The system of claim 7, wherein the mask is in communication with the pure oxygen tank, or the purified compressed air tank system, or rebreather system, via connection tubes to provide breathable air to the subject while undergoing an fMRI scan.

9. The system of claim 1, wherein an exterior capsule valve is attached to the outside of the capsule to restrict air from re-entering the interior of the capsule and maintain a vacuum-sealed environment while undergoing an fMRI scan.

10. The system of claim 1, wherein the capsule is configured to receive a human within the interior of a capsule while undergoing an fMRI scan.

11. The system of claim 1, wherein the capsule is configured to receive an animal within the interior of the capsule while undergoing an fMRI scan.

12. The system of claim 11, further comprising a restraint system including one or more straps to restrain the animal within the interior of the capsule while undergoing an fMRI scan.

13. A method for measuring a subject's baseline (i.e., resting-state) auditory cortex activity using an fMRI machine, comprising the steps of:
i. positioning a subject within a hemicylindrical capsule;
ii. providing the subject with a mask in communication with a non-magnetic tank system comprising a purified compressed air tank, pure oxygen tank, and/or diluent tank, to provide the subject with breathable air during an fMRI scan;
iii. removing air particles from the hemicylindrical capsule via an exterior air particle vacuum to provide a silent environment within the hemicylindrical capsule;
iv. measuring the human subject's baseline auditory cortex using an fMRI machine to detect tinnitus and characterize tinnitus severity by way of leveraging machine learning algorithms trained on a data set comprised of baseline auditory cortex data recorded using the fMRI machine, collected from both tinnitus sufferers and non-tinnitus sufferers.

14. The system of claim 13, wherein the capsule is a hemicylindrical tube including a flat bottom, wherein the flat bottom is retrofitted onto an fMRI scanning bed.

15. The system of claim 13, further comprising a capsule air pressure monitor to monitor pressure within the interior of the capsule.

16. The method of claim 13, wherein the capsule is comprised of a capsule door and an exterior capsule latch to hermetically seal the capsule.

17. The method of claim 13, further comprising an interior capsule latch to permit the opening of the capsule by the subject from the interior of the capsule.

18. The method of claim 13, wherein an exterior capsule valve is attached to the outside of the capsule to restrict air from re-entering the interior of the capsule and maintain a vacuum-sealed environment while undergoing an fMRI scan.

19. The method of claim 3, wherein the capsule is configured to receive an animal within the interior of the capsule while undergoing an fMRI scan.

20. The method of claim 13, further comprising a restraint system including one or more straps to restrain the animal within the interior of the capsule while undergoing an fMRI scan.
